(19) United States
(12) Patent Application Publication
(10) Pub. No.: US 2021/0366993 A1
(43) Pub. Date: Nov. 25, 2021

(54) OLED DISPLAY PANEL AND MANUFATURING METHOD THEREOF

(71) Applicant: WUHAN CHINA STAR OPTOELECTRONICS SEMICONDUCTOR DISPLAY TECHNOLOGY CO., LTD., Wuhan, Hubei (CN)

(72) Inventors: Zesheng CHEN, Wuhan, Hubei (CN); Wenliang GONG, Wuhan, Hubei (CN)

(21) Appl. No.: 16/489,409

(22) PCT Filed: Apr. 10, 2019
(86) PCT No.: PCT/CN2019/082083

§ 371 Date: Aug. 28, 2019

(30) Foreign Application Priority Data
Feb. 28, 2019 (CN) 201910152005.9

(51) Int. Cl. H01L 27/32; H01L 51/52; H01L 51/56

(52) U.S. Cl. CPC H01L 27/322; H01L 51/5237; H01L 51/5284; H01L 51/56; H01L 51/5268

(57) ABSTRACT

An organic light emitting diode (OLED) display panel and a manufacturing method thereof are provided. The OLED display panel includes a display device substrate, an encapsulation layer disposed on the display device substrate, and a color filter substrate disposed on the encapsulation layer. The display device substrate includes a display zone; and the color filter substrate includes a light-transmitting zone corresponding to a display zone, and a shading zone. The light-transmitting zone on the color filter substrate is provided with a scattering structure including a plurality of bulges to scatter ambient light.

### FIELD OF INVENTION

The present invention relates to the field of display techniques. In particular, the present invention relates to an organic light emitting diode (OLED) display panel and its manufacturing method.

### BACKGROUND OF INVENTION

A polaroid (POL) enables effective reduction of the reflectance of a panel in high-intensity light; however, it will lose approximately 58% of the emitted light. That extremely increases lifespan burden for an organic light emitting diode (OLED). On the other hand, if the POL has a larger thickness and is made of fragile material, it is not conducive to the development of dynamic bending products.

In this sector, a technique for using a color filter substrate to instead of the POL is able to effectively increase the light-emitting efficiency. However, for the spin-coated or ink-jet printed color filter substrate, due to its own property, there is still a higher reflection effect on the self-luminance of the OLED and the ambient light, thereby reducing contrast of an OLED display panel.

### Technical Problem

For the spin-coated or ink-jet printed color filter substrate, there is a higher reflection effect on the self-luminance of the OLED and the ambient light.

### SUMMARY OF INVENTION

The present invention provides an OLED display panel. The OLED display panel includes:

a display device substrate including a display zone;

an encapsulation layer disposed on the display device substrate; and

a color filter substrate disposed on the encapsulation layer, and the color filter substrate includes a light-transmitting zone corresponding to the display zone, and a shading zone,

and wherein the light-transmitting zone on the color filter substrate is provided with a scattering structure including a plurality of bulges to scatter the ambient light.

Furthermore, a width of the bulges is less than 600 nm.

Furthermore, a longitudinal cross-section of the bulges is triangular.

Moreover, the longitudinal cross-section of the bulges is an isosceles triangle which has base angles greater than 45 degrees.

Moreover, the bulges are arranged with gaps, and a total area of all of the gaps between the bulges is 0.2 to 0.5 times a total area of the light-transmitting zone.

Also, the longitudinal cross-section of the bulges is trapezoidal.

The present invention further provides a manufacturing method of the OLED display panel. The method includes:

a step S10 of providing the display device substrate including the display zone;

a step S20 of forming the encapsulation layer on the display device substrate;

a step S30 of disposing the color filter on the encapsulation layer, and aligning the color filter with the display zone so as to form the light-transmitting zone;

a step S40 of patterning the color filter to form the scattering structure including a plurality of the bulges on the color filter; and

a step S50 of coating a black matrix on the encapsulation layer to form the shading zone.

Furthermore, the width of the bulges is less than 600 nm.

Furthermore, the longitudinal cross-section of the bulges is triangular or trapezoidal.

Also, the bulges are arranged with gaps, and the total area of all of the gaps between the bulges is 0.2 to 0.5 times the total area of the light-transmitting zone.

### Advantageous Effects

By providing the scattering structure at the light-transmitting zone on the color filter substrate, it can exert a certain anti-reflection effect on the transmitted light. The scattering structure is a microstructure having a grating-like effect, thereby increasing the transmittance of the color filter substrate and reducing the reflection effect of a surface on the self-luminance of the OLED and the ambient light so as to enhance the contrast of the OLED display panel.

### DESCRIPTION OF DRAWINGS

In order to more clearly illustrate embodiments or technical solutions in the prior art, the drawings required for using in the description of the embodiments or the prior art will be briefly described below. Obviously, the drawings in the following description are only some of the embodiments of the present invention. For ordinary technicians in the art, other drawings may also be obtained from these drawings without paying for creative labor.

FIG. 1 is a schematically structural view of an organic light emitting diode (OLED) display panel according to the detailed description of the embodiments of the present invention;

FIG. 2 is a schematically structural view of the OLED display panel according to a first embodiment of the present invention;

FIG. 3 is a schematically structural view of a scattering structure according to the first embodiment of the present invention;

FIGS. 4 to 6 are experimental simulation diagrams of the light transmittance of a color filter substrate to different wavelengths of the light when base angles of a longitudinal cross-section of bulges are at different angles in the first embodiment of the present invention;

FIG. 7 is a schematically structural view of the scattering structure according to a second embodiment of the present invention;

FIGS. 8 to 10 are experimental simulation diagrams of the light transmittance of the color filter substrate to different wavelengths of the light when gaps in the scattering structure have different occupied ratios in the second embodiment of the present invention;

FIG. 11 is a schematically structural view of the scattering structure according to a third embodiment of the present invention;

FIGS. 12 to 14 are experimental simulation diagrams of the light transmittance of the color filter substrate to different wavelengths of the light when the longitudinal cross-section of the bulges is different in shapes in the third embodiment of the present invention;

FIG. 15 is a schematic view of manufacturing steps of the OLED display panel according to the detailed description of the embodiments of the present invention;

FIGS. 16 to 19 are schematic views of a manufacturing procedure of the OLED display panel according to the detailed description of the embodiments of the present invention;

### REFERENCE SYMBOLS

10 display device substrate; 11 substrate; 12 semiconductor layer; 13 the first gate insulator layer; 14 the first metal insulator layer; 15 the second gate insulator layer; 16 the second metal insulator layer; 17 interlayer dielectric layer; 18 source-drain metal layer; 19 flat layer; 101 pixel defining layer; 102 light-emitting functional layer; 103 display zone; 20 encapsulation layer; 30 color filter substrate; 31 light-transmitting zone; 32 shading zone; 40 scattering structure; 41 bulge; 42 gap

### DETAILED DESCRIPTION OF PREFERRED EMBODIMENTS

Referring to the accompanying drawings, the description of following embodiments is provided to illustrate the specific embodiment practiced by the present invention. Directional terms described by the present invention, such as upper, lower, front, back, left, right, inner, outer, side, and etc., are only directions by referring to the accompanying drawings. Therefore, the used directional terms are applied to describe and understand the present invention, but the present invention is not limited thereto. In the drawings, units with the similar structure are represented by the same reference symbols.

The present invention is directed to a technical problem that a spin-coated or ink-jet printed color filter substrate has a high reflection effect on the self-luminance of the organic light emitting diode (OLED) and the ambient light in the existing OLED display panel. The present invention is able to solve the above problem.

### The First Embodiment

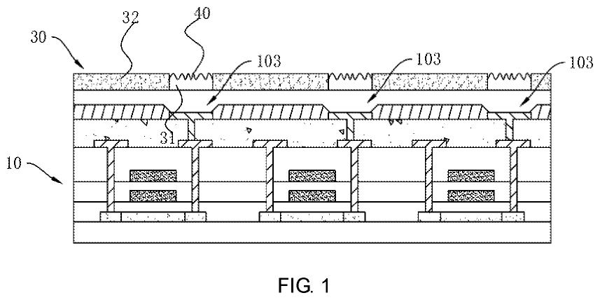

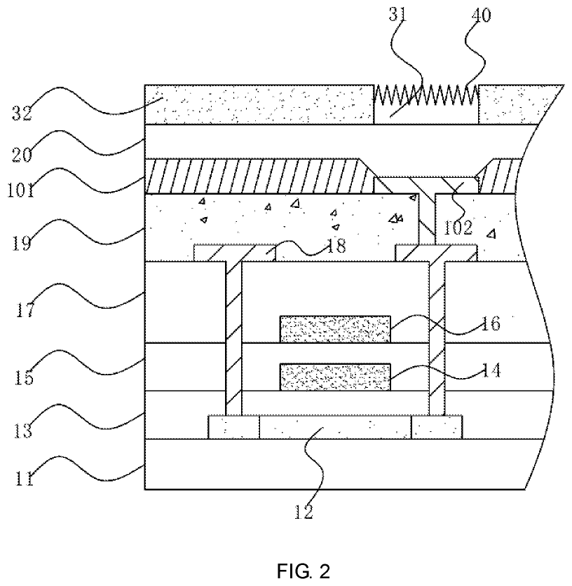

An OLED display panel, as shown in FIG. 1 and FIG. 2, includes a display device substrate 10, an encapsulation layer 20 disposed on the display device substrate 10 and a color filter substrate 30 disposed on the encapsulation layer 20.

Wherein the display device substrate 10 includes a display zone 103, and the color filter substrate 30 includes a light-transmitting zone 31 corresponding to the display zone 103, and a shading zone 32 formed by a black matrix.

Wherein the light-transmitting zone 31 on the color filter substrate 30 is provided with a scattering structure 40 to scatter the ambient light. The scattering structure 40 includes a plurality of bulges 41, where a width of the bulges 41 is less than 600 nm.

By the scattering structure 40 disposed at the light-transmitting zone 31 of the color filter substrate 40, it is known to technicians in the art that when a size of a microstructure is smaller than a specific feature size, it can exert a certain anti-reflection effect on the transmitted light. The scattering structure 40 is the microstructure having a grating-like effect, thereby increasing the transmittance of the color filter substrate 30 and reducing the reflection effect of a surface on the ambient light so as to enhance the contrast of the OLED display panel. Using the color filter substrate 30 to instead of a polaroid (POL) is able to reduce a thickness of a light-emitting functional layer 102 located on the display zone 103, and increase the light-emitting efficiency to improve the display effect.

In one embodiment, the width of the bulges 41 is less than 200 nm.

On the basis of producing the microstructure on a surface of the color filter substrate 30, the feature size and the characteristic of the microstructure are designed, such that there are a preferable transmittance and a surface anti-reflection design for the microstructure on the surface of the color filter substrate 30, and it can further increase the transmittance of the color filter substrate 30, thereby further enhancing the contrast of the OLED display panel.

Specifically, the display device substrate 10 includes a substrate 11, a semiconductor layer 12 and a first gate insulator layer 13 disposed on the substrate 11, a first metal layer 14 and a second gate insulator layer 15 disposed on the first gate insulator layer 13, a second metal insulator layer 16 and a interlayer dielectric layer 17 disposed on the second gate insulator layer 15, a source-drain metal layer 18 and a flat layer 19 disposed on the interlayer dielectric layer 17, as well as a pixel defining layer 101 and a light-emitting functional layer 102 disposed on the flat layer 19.

Wherein the first gate insulator layer 13 covers the semiconductor layer 12; the second gate insulator layer 15 covers the first metal layer 14; the interlayer dielectric layer 17 covers the second metal insulator layer 16; the source-drain metal layer 18 extends downwardly to be in contact with an ion-doped region of the semiconductor layer 12; and an anode metal layer of the light-emitting functional layer 102 extends downwardly to be in contact with the source-drain metal layer 18.

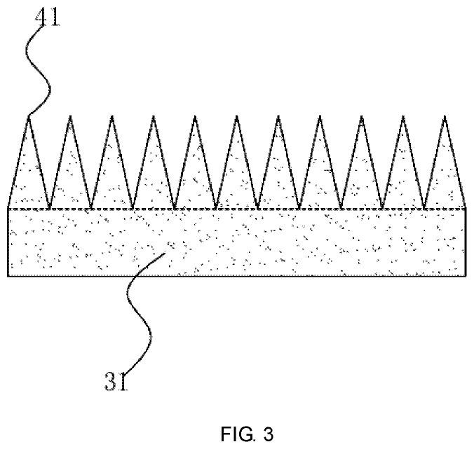

As shown in FIG. 3, a longitudinal cross-section of the bulges is triangular, and bottom sides of the bulges 41 are disposed on the color filter substrate 30. Furthermore, the longitudinal cross-section of the bulges is an isosceles triangle which has base angles greater than 45 degrees.

In one embodiment, the base angles of the bulges are greater than 60 degrees. The anti-reflection effect of the scattering structure 40 on the transmitted light is further improved, and the reflection effect on the ambient light is simultaneously reduced, and the contrast of the OLED display panel is enhanced.

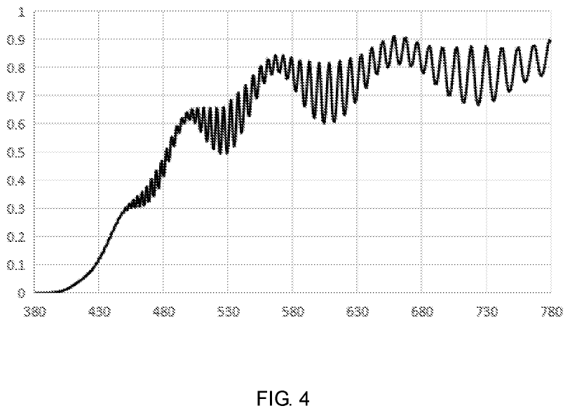

As shown in FIGS. 4 to 6, it should be illustrated that FIGS. 4 to 6 show experimental simulation diagrams of the light transmittance of the color filter substrate 30 to different wavelengths of the light when the base angles of the longitudinal cross-section of the bulges 41 are at different angles. Wherein the abscissa indicates the wavelength of the light, and the smaller the oscillation amplitude of the wave line in the figures, the higher the light transmittance. The oscillation amplitude is a distance between adjacent wave peaks and wave troughs.

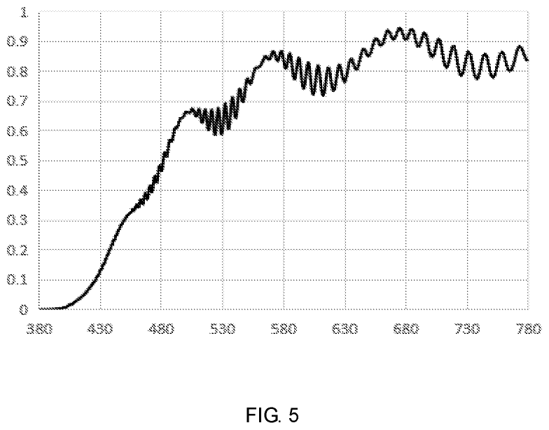

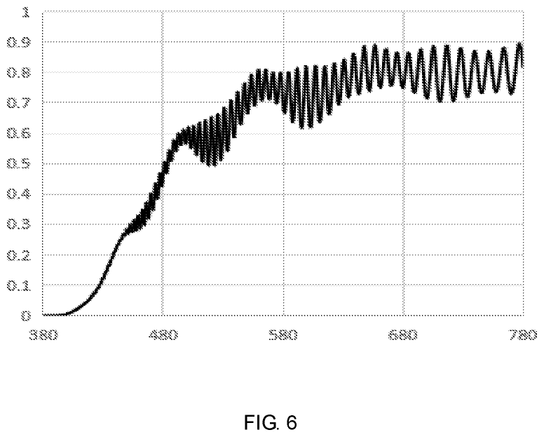

FIG. 4 shows the simulation diagram that the base angles of the longitudinal cross-section of the bulges 41 are 30 degrees. FIG. 5 shows the simulation diagram that the base angles of the longitudinal cross-section of the bulges 41 are 70 degrees. FIG. 6 shows the simulation diagram that there is no scattering structure. For the technicians in the art, it is apparent from the simulation diagrams that when the base angles of the longitudinal cross-section of the bulges 41 are 70 degrees, the oscillation amplitude of the wave line is small, so the light transmittance is high.

In one embodiment, it should be illustrated that the scattering structure 40 can also be in the form of a microlens to increase the transmittance of the OLED display panel from a geometrical optic perspective.

### The Second Embodiment

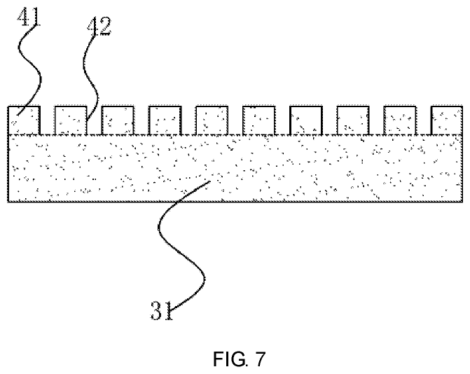

An OLED display panel, as shown in FIG. 7, differs from the first embodiment only in the shape of the scattering structure 40.

Specifically, the longitudinal cross-section of the bulges 41 is rectangular, and the bulges 41 are arranged with gaps 42, and a total area of all of the gaps 42 between the bulges 41 is 0.2 to 0.5 times a total area of the light-transmitting zone.

By the gaps 42 in the scattering structure 40 having a suitable occupied ratio, the anti-reflection effect of the scattering structure 40 on the transmitted light is further improved, while the reflection effect of the ambient light is reduced, and the contrast of the OLED display panel is enhanced.

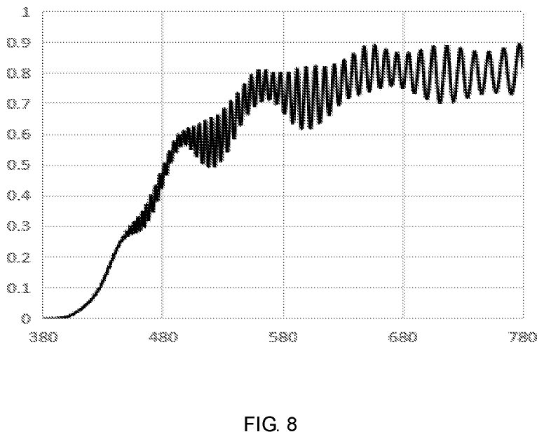

As shown in FIGS. 8 to 10, it should be illustrated that FIGS. 8 to 10 show the experimental simulation diagrams of the light transmittance of the color filter substrate 30 to different wavelengths of the light when the gaps 42 in the scattering structure 40 have different occupied ratios.

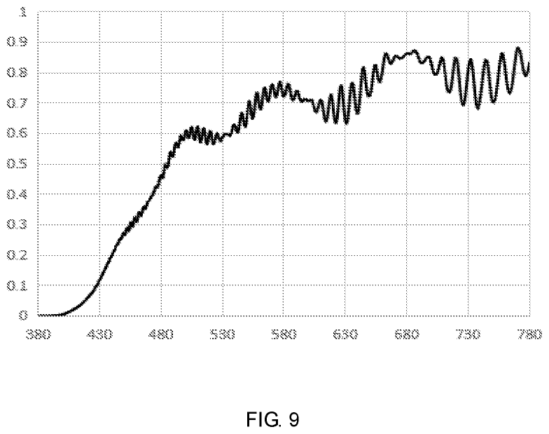

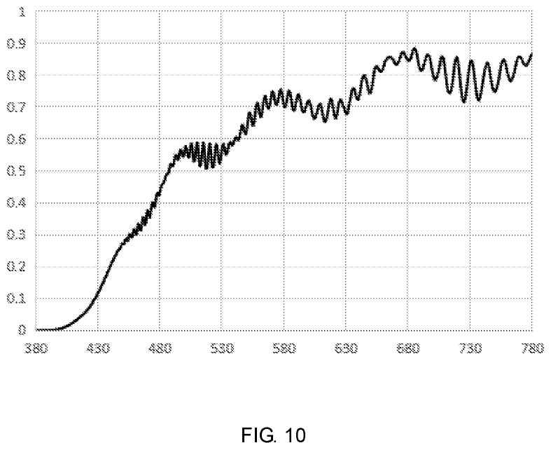

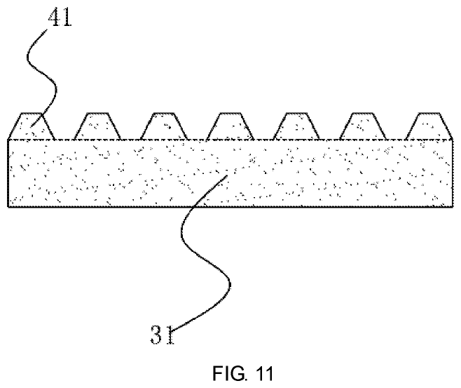

FIG. 8 shows the simulation diagram that there is no scattering structure. FIG. 9 shows the simulation diagram that the occupied ratio of the gaps 42 in the scattering structure 40 is 0.7. FIG. 10 shows the simulation diagram that the occupied ratio of the gaps 42 in the scattering structure 40 is 0.5. For the technicians in the art, it is apparent from the simulation diagrams that when the occupied ratio of the gaps 42 in the scattering structure 40 is 0.5, the oscillation amplitude of the wave line is small, so the light transmittance is high.

### The Third Embodiment

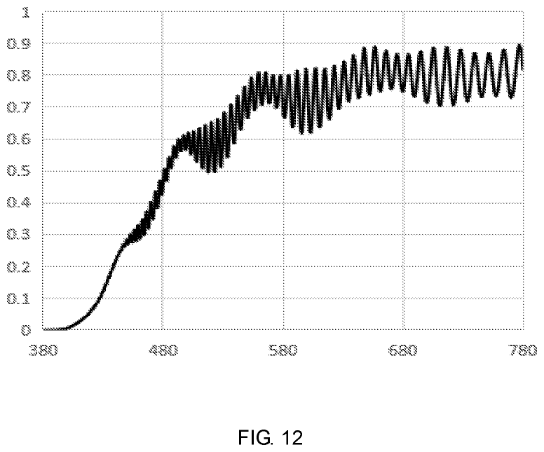

As shown in FIGS. 12 to 14, it should be illustrated that FIGS. 12 to 14 show the experimental simulation diagrams of the light transmittance of the color filter substrate 30 to different wavelengths of the light when the longitudinal cross-section of the bulges 41 is different in shapes.

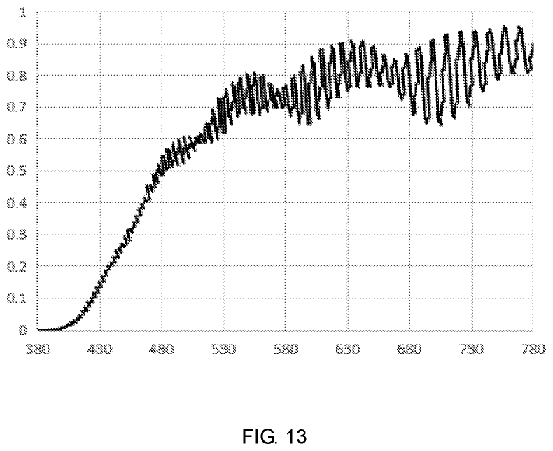

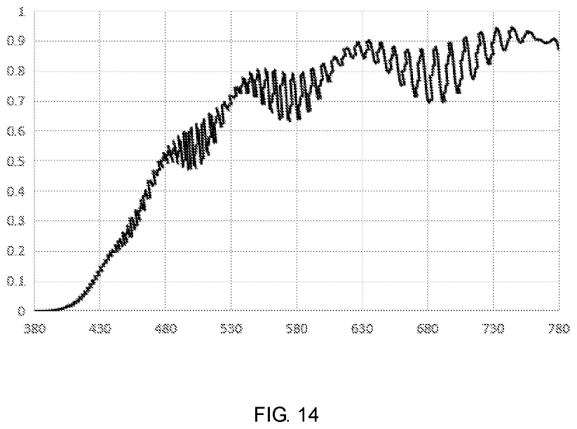

FIG. 12 shows the simulation diagram that there is no scattering structure. FIG. 13 shows the simulation diagram that the longitudinal cross-section of the bulges 41 is regular trapezoidal. FIG. 14 shows the simulation diagram that the longitudinal cross-section of the bulges 41 is inverted trapezoidal. It is known from the figures that when the longitudinal cross-section of the bulges 41 is regular trapezoidal or inverted trapezoidal, the oscillation amplitude of the wave line is small, so the light transmittance is high.

### The Fourth Embodiment

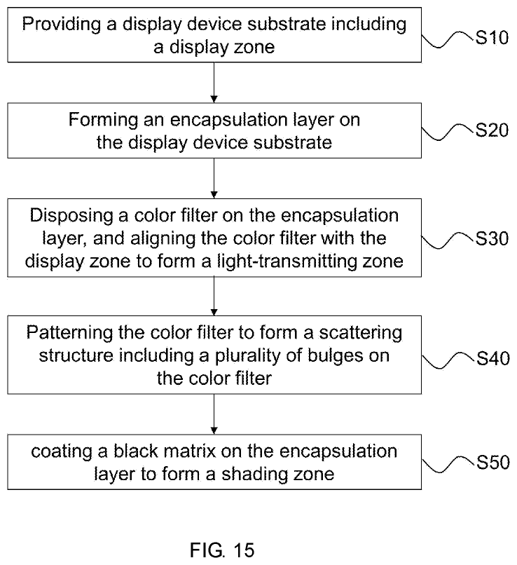

Based on the above OLED display panel, the present invention also provides a manufacturing method of the OLED display panel, as shown in FIG. 15, and the method includes:

a step S10 of providing the display device substrate 10 including the display zone 103;

a step S20 of forming the encapsulation layer 20 on the display device substrate 10;

a step S30 of disposing the color filter on the encapsulation layer 20, and aligning the color filter with the display zone 103 so as to form the light-transmitting zone 31;

a step S40 of patterning the color filter to form the scattering structure 40 including a plurality of the bulges 41 on the color filter; and

a step S50 of coating a black matrix on the encapsulation layer 20 to form the shading zone 32.

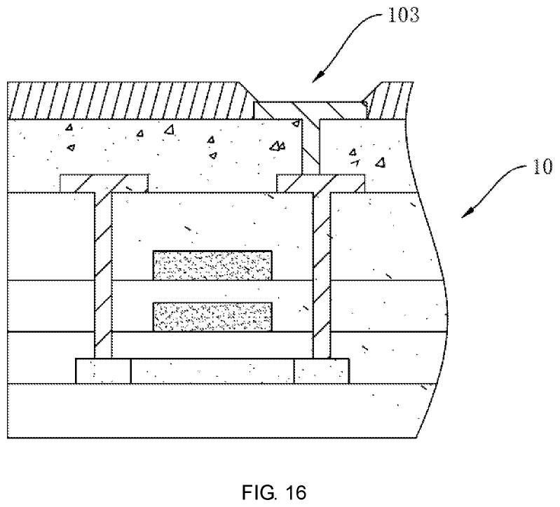

As shown in FIGS. 16 to 18, FIGS. 16 to 18 are schematic views of a manufacturing procedure of the OLED display panel.

As shown in FIG. 16, the display device substrate 10 is formed.

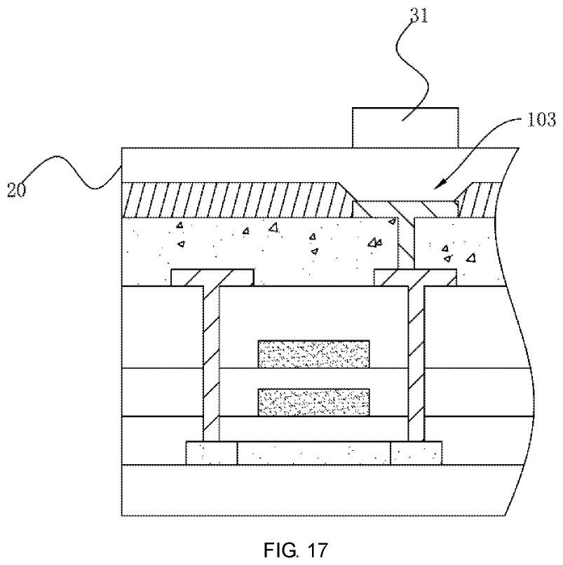

As shown in FIG. 17, after forming the encapsulation layer 20 on the display device substrate 10, the color filter is disposed on the encapsulation layer 20, and aligned with the display zone 103 by photolithography so as to form the light-transmitting zone 31.

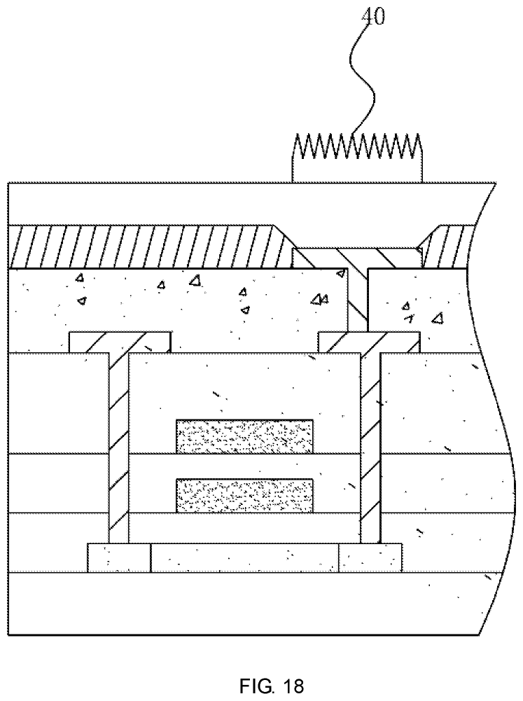

As shown in FIG. 18, the, manufactured color filter is extruded by means of the nanoimprint to form the scattering structure 40 having the feature size on the surface of the color filter. The scattering structure 40 includes a plurality of the bulges 41, and the width of the bulges 41 is less than 600 nm.

Furthermore, the width of the bulges 41 is less than 200 nm.

In one embodiment, the longitudinal cross-section of the bulges 41 is triangular or trapezoidal.

Furthermore, when the longitudinal cross-section of the bulges 41 is triangular, the longitudinal cross-section of the bulges 41 is the isosceles triangle which has base angles greater than 45 degrees.

When the longitudinal cross-section of the bulges 41 is trapezoidal, the longitudinal cross-section of the bulges 41 can be regular trapezoidal and also inverted trapezoidal.

In another embodiment, the bulges 41 are arranged with the gaps, and the total area of all of the gaps 42 between the bulges 41 is 0.2 to 0.5 times the total area of the light-transmitting zone 31.

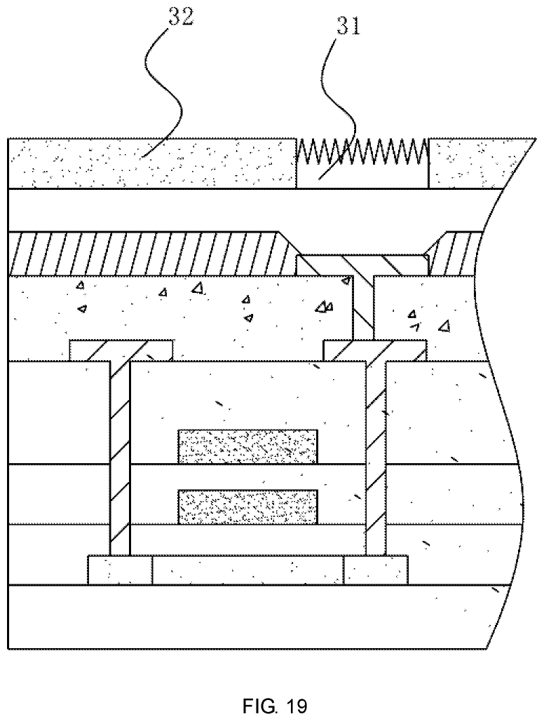

As shown in FIG. 19, the encapsulation layer 20 is coated with the black matrix to form the shading zone 32, and the shading zone 32 and the light-transmitting zone 31 constitute the color filter substrate 30.

The beneficial effects of the present invention are by providing the scattering structure 40 at the light-transmitting zone 31 of the color filter substrate 30, it is known to the technicians in the art that when the size of the microstructure is smaller than the specific feature size, it can exert the certain anti-reflection effect on the transmitted light. The scattering structure 40 is the microstructure having a grating-like effect, thereby increasing the transmittance of the color filter substrate 30 and reducing the reflection effect of the surface on the self-luminance of the OLED and the ambient light so as to enhance the contrast of the OLED display panel.

In summary, although the present invention has been disclosed with preferred embodiments, they don't intend to limit the present invention, and the ordinary technicians in the art can make various changes and modifications without departing from the spirit and the scope of the present invention. Therefore, the protection of the present invention is defined by the scope of the claims.

What is claimed is:

1. An organic light emitting diode (OLED) display panel, comprising:
a display device substrate including a display zone;
an encapsulation layer disposed on the display device substrate; and
a color filter substrate disposed on the encapsulation layer, and including a light-transmitting zone corresponding to a display zone, and a shading zone;
wherein the light-transmitting zone on the color filter substrate is provided with a scattering structure including a plurality of bulges to scatter ambient light.

2. The OLED display panel according to claim 1, wherein a width of the bulges is less than 600 nm.

3. The OLED display panel according to claim 1, wherein a longitudinal cross-section of the bulges is triangular.

4. The OLED display panel according to claim 3, wherein the longitudinal cross-section of the bulges is an isosceles triangle which has base angles greater than 45 degrees.

5. The OLED display panel according to claim 1, wherein the bulges are arranged with gaps, and a total area of all of the gaps between the bulges is 0.2 to 0.5 times a total area of the light-transmitting zone.

6. The OLED display panel according to claim 1, wherein a longitudinal cross-section of the bulges is trapezoidal.

7. A manufacturing method of an organic light emitting diode (OLED) display panel, comprising:
a step S10 of providing a display device substrate including a display zone;
a step S20 of forming an encapsulation layer on the display device substrate;
a step S30 of disposing a color filter on the encapsulation layer, and aligning the color filter with the display zone so as to form a light-transmitting zone;
a step S40 of patterning the color filter to form a scattering structure including a plurality of bulges on the color filter; and
a step S50 of coating a black matrix on the encapsulation layer to form a shading zone.

8. The manufacturing method of the OLED display panel according to claim 7, wherein a width of the bulges is less than 600 nm.

9. The manufacturing method of the OLED display panel according to claim 7, wherein a longitudinal cross-section of the bulges is triangular or trapezoidal.

10. The manufacturing method of the OLED display panel according to claim 7, wherein the bulges are arranged with gaps, and a total area of all of the gaps between the bulges is 0.2 to 0.5 times a total area of the light-transmitting zone.
